(19) United States
(12) Patent Application Publication
(10) Pub. No.: US 2010/0127786 A1
(43) Pub. Date: May 27, 2010

(54) LOW NOISE OSCILLATORS

(76) Inventors: Roger L. Clark, Windham, NH (US); William W. Cooper, Townsend, MA (US); Mark J. Gugliuzza, Tewksbury, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 12/276,596

(22) Filed: Nov. 24, 2008

(51) Int. Cl. H03L 5/00

(52) U.S. Cl. 331/109

(57) ABSTRACT

An oscillator having: a transistor; a resonant circuit coupled between an output electrode of the transistor and a control electrode of the transistor; and a dc bias circuit for the transistor. The dc bias circuit comprises: a voltage producing circuit and a differential amplifier. The differential amplifier includes: a first input coupled to a fixed reference voltage; a second input coupled to the voltage producing circuit, such voltage producing circuit producing a voltage at the second input of the difference amplifier related to current passing through the output electrode of the transistor; and an output coupled to the control electrode of the transistor.

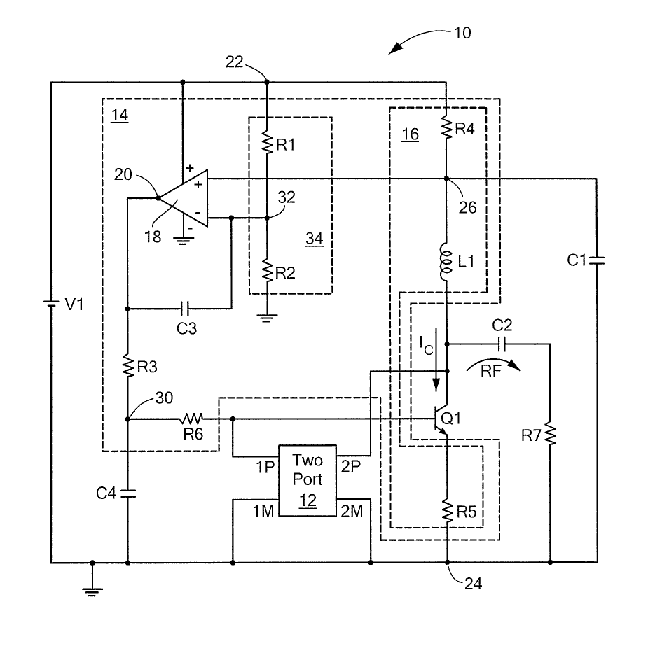

### TECHNICAL FIELD

The present invention relates to RF oscillators and more particularly to RF oscillators having low levels of phase noise.

### BACKGROUND

As is known in the art, low noise oscillators have a wide range of applications such as in navigation, radars and communication systems. As is also known in the art, with transistor oscillators, flicker noise from the transistors may significantly degrade oscillator phase noise. One technique used to produce low noise oscillators is to screen oscillator transistors for devices having low phase noise. This is time consuming, costly and can sometimes lead to unpredictable yields. Obtaining RF transistors with flicker noise much less than 1 kHz is desired, but is generally considered impractical. More particularly, RF oscillator phase noise is a dominant factor limiting the performance of many systems. A time based related attribute is the short-term stability or Allan variance. The basic mechanisms of phase noise generation in oscillators are well understood and described in the literature. An example is the model described D. B. Leeson in an article by D. B. Leeson, entitled “A simple model of feedback oscillator noise spectrum,” Proc. IEEE, vol. 54, pp. 329-330, February 1966. This oscillator model is commonly referred to as “Leeson's model”. Many techniques are employed to reduce the phase noise of oscillators, but generally these techniques relate to using transistors with lower 1/f phase noise or higher Q resonators in the feedback circuit.

Phase noise is often described by its spectral properties. For example, phase noise can have a 1/fⁿ characteristic, with n being an integer. For oscillator circuits, n generally varies from 0 to 3. As described in by D. B. Leeson, in the paper entitled “A simple model of feedback oscillator noise spectrum,” Proc. IEEE, vol. 54, pp. 329-330, February 1966, electronic noise within the resonator bandwidth is increased such that flicker noise is converted into 1/f³ phase noise when the device is embedded into a high Q oscillator circuit. The implication of this conversion is that noise within the resonator bandwidth is greatly increased. Obtaining lower phase noise then requires either lower 1/f phase noise transistors or higher Q resonators. In particular, the 1/f phase noise of a RF transistor relates to the phase noise at small offset frequencies from the center resonance frequency of the oscillation signal. For example, when referring to 1/f phase noise in a 1 GHz oscillator, the 1/f term applies to noise having a 1/f spectral shape when offset from the 1 GHz output. Although transistor 1/f phase noise is generally attributed to material and surface defects, the precise mechanisms are not well understood.

The origin of 1/f phase noise can be associated with the actual flicker noise of the transistor, but the specific mechanisms of conversion are also not well understood. Obtaining RF transistors having very low 1/f phase noise is quite difficult due to compromises between RF performance and flicker noise.

An analysis was presented by Eva S. Ferre-Pikal, Fred L. Walls, in a paper entitled Guidelines for Designing BJT Amplifiers with Low 1/f AM and PM noise, IEEE Transactions on Ultrasonics, Ferroelectronics and Frequency Control, Vol. 44, No. 2, March 1997 which relates amplifier 1/f phase noise with low frequency voltage fluctuations. Modulation of the collector-base capacitance was proposed as a means of converting flicker noise to residual 1/f phase noise.

In a paper entitled Reduction of Phase Noise in Linear HBT Amplifiers Using Low-Frequency Active Feedback by Eva S. Ferre-Pikal, IEEE Transactions on Circuits and Systems, Vol. 51, No. 8, August 2004 the author attempted to stabilize a conventionally biased RF transistor by use of an instrumentation amplifier. The instrumentation amplifier was configured in a conventional topology. There was evidence that additional stability of the transistor bias point could suppress 1/f phase noise. However this topology also introduced several additional resistive components as potential sources of noise and had limited noise suppression. These devices were not embedded into or related to low phase noise oscillators.

The desire is to provide an RF oscillator with very low phase noise. In addition, it is desired to minimize RF power variations with temperature and process variations.

### SUMMARY

In accordance with the present invention, an oscillator is provided having: a transistor; a resonant circuit coupled between an output electrode of the transistor and a control electrode of the transistor; and a dc bias circuit for the transistor. The de bias circuit comprises: a voltage producing circuit and a differential amplifier. The differential amplifier includes: a first input coupled to a fixed reference voltage; a second input coupled to the voltage producing circuit, such voltage producing circuit producing a voltage at the second input of the difference amplifier related to current passing through the output electrode of the transistor; and an output coupled to the control electrode of the transistor.

In one embodiment, the oscillator includes a voltage source having: one potential coupled to one terminal of the voltage producing circuit; and a second potential coupled to a second terminal of the voltage producing circuit; and wherein a third terminal of the voltage producing circuit is coupled to the second input of the differential amplifier.

In one embodiment, the voltage producing circuit includes a first resistor coupled between the first potential and the second input of the differential amplifier and a second resistor between an additional electrode of the transistor and the second potential.

In one embodiment, the oscillator includes an inductor coupled between the second input of the differential amplifier and the output electrode of the transistor.

In one embodiment, the oscillator includes a capacitor coupled between the first input of the differential amplifier and the output of the differential amplifier.

In one embodiment, the oscillator includes a third resistor and a fourth resistor connected to the third resistor at a node, such node being coupled to the second potential through a capacitor, the third resistor being coupled between the output of the differential amplifier and the node and the fourth resistor being coupled between the node and the control electrode of the transistor.

In one embodiment, the fixed voltage is a voltage produced by a resistor divider coupled between the first and second potentials.

Thus, with such an arrangement, flicker noise of the oscillator is reduced by actively controlling biasing and low frequency modulation. This invention uses a novel topology to reduce flicker noise and improve phase noise. The technique is applicable to a broad class of oscillators.

The details of one or more embodiments of the invention are set forth in the accompanying SINGLE FIGURE of an oscillator according to the invention and description below. Other features, objects, and advantages of the invention will be apparent from the description and drawings, and from the claims.

### DESCRIPTION OF DRAWING

The SINGLE FIGURE is a schematic diagram of an RF oscillator according to the invention.

### DETAILED DESCRIPTION

Referring now to the SINGLE FIGURE, an oscillator 10 is shown. The oscillator includes a transistor Q1; a resonant circuit 12 coupled between an output electrode, here collector electrode, of the transistor Q1 and a control electrode, here base electrode, of the transistor Q1; and a dc bias circuit 14 for the transistor Q1. The dc bias circuit 14 includes: a voltage producing circuit 16; and a differential amplifier 18. The differential amplifier 18 has: a first input (inverting (−) input) coupled to a fixed reference voltage; a second input (non-inverting (+)) coupled to the voltage producing circuit 16, such voltage producing circuit producing a voltage at the second input (non-inverting (+)) of the difference amplifier 18 related to current Ic passing through the output electrode (collector) of the transistor Q1; and an output 20 coupled to the control electrode (base) of the transistor Q1. A voltage source V1 has: one potential (+) coupled to one terminal of 22 the voltage producing circuit 14; and a second potential (−) coupled to a second terminal 24 of the voltage producing circuit 14. A third terminal 26 of the voltage producing circuit 14 is coupled to the second input (non-inverting (+)) of the differential amplifier 18. The voltage producing circuit 14 includes a first resistor R4 coupled between the first potential and the second input of the differential amplifier (non-inverting (+)) and a second resistor R5 between an additional electrode (emitter) of the transistor Q1 and the second potential (i.e., terminal 24). An inductor L1 is coupled between the second input (non-inverting (+)) of the differential amplifier 18 and the output electrode (collector) of the transistor Q1. A capacitor C3 is coupled between the first input (inverting (−)) of the differential amplifier 18 and the output 20 of the differential amplifier 18. A third resistor R3 and a fourth resistor R6 are connected together at a node 30, such node 30 being coupled to the second potential (i.e., terminal 24) through a capacitor C4, the third resistor R3 being coupled between the output 20 of the differential amplifier 18 and the node 30 and the fourth resistor R6 being coupled between the node 30 and the control electrode (base electrode) of the transistor Q1. The fixed voltage is a voltage produced at node 32 by a resistor divider 34 made up of resisters R1 and R2 coupled between the first and second potentials of the supply V1.

More particularly, the transistor Q1 is the oscillator transistor. The differential amplifier 18 is chosen to have low flicker noise properties. A resistor R7 is the RF load resistor with typical value of 50 ohms. Inductor L1 is used for RF isolation and may also take the form of a distributed transmission line. Capacitor C1 is a bypass capacitor having very low reactance at the oscillation frequency. The two port device is the resonant feedback circuit 12 and could be a lumped element LC, an acoustic resonator such as SAW, or a distributed resonator such as a transmission line or a dielectric resonator. The two-port could include a means of tuning the oscillator frequency such as a varactor diode.

Here the differential amplifier 18 is used to bias and stabilize the oscillator transistor Q1. Transistor Q1 is shown as a bipolar device, but may also be a FET; in which case the control electrode is the gate electrode. The semiconductor material may be silicon, GaAs, GaN or other semiconductor materials.

Biasing is provided by using as the differential amplifier 18 a differential amplifier having low flicker noise. For example, commercially available differential amplifiers are available with a typical flicker noise intercept of less than 10 Hz. A reference voltage formed by the voltage divider of R1 and R2 and also having low flicker noise is used as the inverting input, and a voltage proportional to collector current of the RF transistor is used as the non-inverting input. The feedback path from the voltage at the R4-L1 node is applied to the positive differential amp input due to the 180 phase shift of transistor Q1 at low frequencies. Effectively the amplifier 19 positive input (non-inverting input (+)) becomes a negative feedback path, and the reference voltage at node 32 is applied to what is commonly used as the negative input to the op-amp. The output 20 from the differential amplifier 18 is used to provide a voltage for biasing the input (here emitter) to the RF transistor Q1. Resistor R3, R6 and capacitor C4 serve to isolate the RF signal from the biasing function. An additional capacitor C3 serves as a phase shift component to establish adequate phase margin and ensure that noise processes are not regenerated by the very high differential voltage gain. The biasing configuration ensures that the voltage of the non-inverting input (+) of the differential amplifier 18 will be essentially equal to the voltage of the inverting input (−). Since the noise at the inverting input (−) is derived from a reference voltage at node 32 with very low noise, the noise at the non-inverting input (+) will also be similarly quiet. Any noise in the collector current Ic of the RF transistor Q1 will now be sensed by the biasing circuit 14 and the voltage present at the base of the RF transistor Q1 will be adjusted to compensate for that noise. Noise which is normally present at the collector of the RF transistor Q1 will essentially be translated back to the base of said transistor Q1. However, since the transistor Q1 has a voltage gain from the collector to base electrode, voltage noise will similarly be reduced by this voltage gain. Noise processes associated with modulation of the collector to base capacitance, and within the bandwidth of the biasing circuitry, will similarly be reduced. Resistor R5 provides additional negative feedback to stabilize the oscillation circuit.

Since the biasing circuitry extends down to DC, the oscillator frequency is also stabilized with respect to variation in temperature and parametric variations of the RF transistor. The circuit can be implemented from discrete devices or as an integrated circuit.

A number of embodiments of the invention have been described. Nevertheless, it will be understood that various modifications may be made without departing from the spirit and scope of the invention. For example, the invention applies to crystal, SAW, LC and microwave resonant oscillators, and can be implemented with discrete components or as integrated circuit devices. Additionally, inductors and capacitors could be replaced with equivalent function distributed elements, such as microstrip transmission lines, for use at microwave frequencies. Accordingly, other embodiments are within the scope of the following claims.

What is claimed is:

1. An oscillator comprising:
a transistor;
a resonant circuit coupled between an output electrode of the transistor and a control electrode of the transistor;
a dc bias circuit for the transistor, such bias circuit comprising:
a voltage producing circuit;
a differential amplifier having:
a first input coupled to a fixed reference voltage;
a second input coupled to the voltage producing circuit, such voltage producing circuit producing a voltage at the second input of the difference amplifier related to current passing through the output electrode of the transistor; and
an output coupled to the control electrode of the transistor.

2. The oscillator recited in claim 1 including a voltage source having: one potential coupled to one terminal of the voltage producing circuit; and a second potential coupled to a second terminal of the voltage producing circuit; and wherein a terminal of the voltage producing circuit is coupled to the second input of the differential amplifier.

3. The oscillator recited in claim 2 wherein the voltage producing circuit includes a first resistor coupled between the first potential and the second input of the differential amplifier and a second resistor between an additional electrode of the transistor and the second potential.

4. The oscillator recited in claim 3 includes an inductor coupled between the second input of the differential amplifier and the output electrode of the transistor.

5. The oscillator recited in claim 4 including a capacitor coupled between the first input of the differential amplifier and the output of the differential amplifier.

6. The oscillator recited in claim 3 including a third resistor coupled between the output of the amplifier and the control electrode of the transistor.

7. The oscillator recited in claim 3 including a third resistor and a fourth resistor connected to the third resistor at a node, such node being coupled to the second potential through a capacitor, the third resistor being coupled between the output of the differential amplifier and the node and the fourth resistor being coupled between the node and the control electrode of the transistor.

8. The oscillator recited in claim 3 wherein the fixed voltage is a voltage produced by a resistor divider coupled between the first and second potentials.

9. The oscillator recited in claim 8 includes an inductor coupled between the second input of the differential amplifier and the output electrode of the transistor.

10. The oscillator recited in claim 9 including a capacitor coupled between the first input of the differential amplifier and the output of the differential amplifier.

11. The oscillator recited in claim 8 including a third resistor coupled between the output of the amplifier and the control electrode of the transistor.

12. The oscillator recited in claim 8 including a third resistor and a fourth resistor connected to the third resistor at a node, such node being coupled to the second potential through a capacitor, the third resistor being coupled between the output of the differential amplifier and the node and the fourth resistor being coupled between the node and the control electrode of the transistor.
